(19) United States
(12) Patent Application Publication
(10) Pub. No.: US 2026/0142556 A1
(43) Pub. Date: May 21, 2026

(54) DRIVING CIRCUIT WITH IMPROVED STARTUP PERFORMANCE, POWER CONVERSION CIRCUIT COMPRISING THE SAME AND DRIVING METHOD FOR POWER SWITCHING DEVICE

(71) Applicant: Chengdu Monolithic Power Systems Co., Ltd., Chengdu (CN)

(72) Inventors: Ning Bu, Chengdu (CN); Yang-Sheng Lin, Taipei City (TW)

(21) Appl. No.: 19/393,278

(22) Filed: Nov. 18, 2025

(30) Foreign Application Priority Data
Nov. 19, 2024 (CN) 202411658569.7

(51) Int. Cl. H02M 1/088; H02M 1/00; H02M 1/36; H03K 17/042; H03K 17/0812; H03K 17/18

(52) U.S. Cl. CPC H02M 1/088; H02M 1/0012; H02M 1/36; H03K 17/04206; H03K 17/08122; H03K 17/18; H03K 2217/0063; H03K 2217/0072

(57) ABSTRACT

A high-side driving circuit, comprising an input terminal, an output terminal, and a power supply terminal. The input terminal receives a high-side switching control signal. The output terminal is coupled to a control terminal of a high-side power switching device and configured to provide a high-side driving signal to control the turn-on and turn-off switching of the high-side power switching device. The power supply terminal receives a the bootstrap voltage from a bootstrap capacitor. The high-side driving circuit is configured to: during a startup phase or initialization phase of the high-side driving circuit, output the high-side driving signal after a delay period in response to the bootstrap voltage becoming higher than a first under-voltage threshold; and during a stable operation state of the high-side driving circuit, stop outputting the high-side driving signal in response to the bootstrap voltage becoming lower than a second under-voltage threshold.

### CROSS-REFERENCE TO RELATED APPLICATIONS

The present application claims priority to, and the benefit of, Chinese Application No. 202411658569.7, filed on Nov. 19, 2024, which is incorporated herein by reference in its entirety.

### TECHNICAL FIELD

The present invention relates to electronic circuits, and more specifically, to a driving circuit with improved startup performance, a power conversion circuit including the driving circuit, and a driving method for driving a power switching device.

### BACKGROUND

In a bridge switching power supply, a high-side power switching device and a low-side power switching device are respectively driven by a corresponding high-side driving circuit and low-side driving circuit to be turned-on and turned-off. To ensure proper turn-on of the high-side power switching device, a voltage difference between the high-side driving signal output by the high-side driving circuit and a voltage on a drain of the high-side power switching device need to be sufficiently large. Therefore, the high-side driving circuit usually includes a bootstrap circuit to provide a high enough high-side driving voltage to properly turn on the high-side power switching device.

The high-side and low-side driving circuits are respectively configured to enhance driving capabilities of high-side and low-side switching control signals (that is, increase an amplitude difference between their logic high and low levels) and to output high-side and low-side driving signals that are respectively synchronized with the high-side and low-side switching control signals. However, during system startup, the startup time of the low-side driving circuit is typically within 2 μs, whereas, due to limitations of the charging capability of the bootstrap capacitor, the startup of the high-side driving circuit is significantly slower, causing the driving of the high-side power switching device to lag behind that of the low-side power switching device.

Therefore, it is desirable to provide a solution for quickly starting the high-side driving circuit while improving reliability to ensure safe operation of the bridge switching power supply.

### SUMMARY

An embodiment of the present invention provides a high-side driving circuit for driving a high-side power switching device, including: an input terminal, an output terminal, and a power supply terminal. The input terminal is configured to receive a high-side switching control signal. The output terminal is coupled to a control terminal of the high-side power switching device and is configured to provide a high-side driving signal to control turn-on and turn-off switching of the high-side power switching device. The power supply terminal is configured to receive a bootstrap voltage from a bootstrap capacitor. The high-side driving circuit is configured to: during a startup phase or an initialization phase of the high-side driving circuit, output the high-side driving signal after a delay period has elapsed since the bootstrap voltage reaches or exceeds a first under-voltage threshold; and during a stable operation state of the high-side driving circuit, stop outputting the high-side driving signal in response to the bootstrap voltage becoming lower than a second under-voltage threshold. The first under-voltage threshold is lower than the second under-voltage threshold.

Another embodiment of the present invention provides a power conversion circuit, including: a high-side power switching device, a low-side power switching device, the high-side driving circuit as described above, a low-side driving circuit, and a bootstrap capacitor. The high-side power switching device includes a first terminal for receiving an input voltage, a second terminal, and a control terminal. The low-side power switching device includes a first terminal coupled to the second terminal of the high-side power switching device, a second terminal coupled to a reference ground, and a control terminal. The high-side driving circuit is coupled to the control terminal of the high-side power switching device and is configured to control turn-on and turn-off switching of the high-side power switching device. The low-side driving circuit is coupled to the control terminal of the low-side power switching device and is configured to control turn-on and turn-off switching of the low-side power switching device. The bootstrap capacitor is coupled between a power supply terminal of the high-side driving circuit and a common terminal of the high-side power switching device and the low-side power switching device, and is configured to provide a bootstrap voltage to the high-side driving circuit.

A further embodiment of the present invention provides a method for operating a high-side driving circuit. The high-side driving circuit is supplied with a supply voltage from a bootstrap capacitor and is configured to output a high-side driving signal to drive a high-side power switching device. The method includes the following steps: detecting whether the supply voltage becomes higher than a first under-voltage threshold during a startup phase or an initialization phase of the high-side driving circuit; outputting the high-side driving signal after a delay period when the supply voltage becomes higher than the first under-voltage threshold; detecting whether the supply voltage becomes lower than a second under-voltage threshold during a stable operation state of the high-side driving circuit; and stopping outputting the high-side driving signal when the supply voltage becomes lower than the second under-voltage threshold. The first under-voltage threshold is lower than the second under-voltage threshold.

It should be understood that the content described in this section is not intended to identify key or essential features of the embodiments of the present application, nor is it used to limit the scope of the application. Other features of the present application will become apparent through the following description.

### BRIEF DESCRIPTION OF DRAWINGS

Further understanding of the present invention can be obtained by referring to the following detailed description and accompanying drawings, in which like elements are denoted by like reference numerals. These drawings are for illustrative purposes only and may therefore show only a portion of the device, and are not necessarily drawn to scale.

FIG. 1 illustrates a schematic block diagram of a power conversion circuit, according to an embodiment of the present invention.

FIG. 2 illustrates a schematic block diagram of a high-side driving circuit for driving a high-side power switching device, according to an embodiment of the present invention.

FIG. 3 illustrates a waveform diagram of a bootstrap voltage on a bootstrap capacitor during a startup phase or an initialization phase of a high-side driving circuit, according to an embodiment of the present invention.

FIG. 4 illustrates a schematic circuit diagram of a high-side driving circuit for driving a high-side power switching device, according to an embodiment of the present invention.

FIG. 5 illustrates an exemplary circuit diagram of a voltage-current reference circuit, according to an embodiment of the present invention.

FIG. 6 illustrates waveform diagrams of a part of signals generated during operation of the high-side driving circuit, according to an embodiment of the present invention.

FIG. 7 illustrates a flowchart of a method for operating a high-side driving circuit, according to an embodiment of the present invention.

### DETAILED DESCRIPTION

Hereinafter, specific embodiments of the present application will be described in detail, and it should be noted that the embodiments described here are only for illustration and are not used to limit the present application. In the following description, some specific details are included to provide a thorough understanding of embodiments. One skilled in the relevant art will identify, however, that the present application can be practiced without one or more specific details. In other instances, well-known structures, materials, processes or operations are not shown or described in detail to avoid obscuring aspects of the present application.

Throughout the specification and claims, the phrases “in an embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

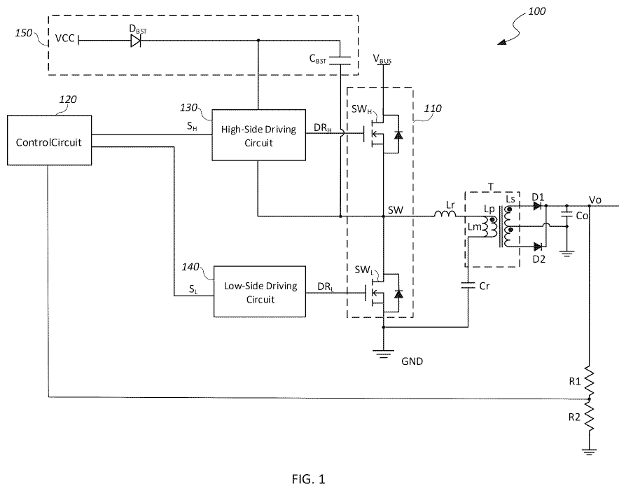

FIG. 1 illustrates a schematic block diagram of a power conversion circuit 100, according to an embodiment of the present invention. As shown in FIG. 1, the power conversion circuit 100 includes a switching circuit 110, a control circuit 120, a high-side driving circuit 130, a low-side driving circuit 140, and a bootstrap circuit 150.

In an embodiment, the switching circuit 110 includes a high-side power switching device SW_{H} and a low-side power switching device SW_{L}. The high-side power switching device SW_{H} has a first terminal, a second terminal, and a control terminal. The first terminal of the high-side power switching device SW_{H} is configured to receive an input voltage V_{BUS}. The low-side power switching device SW_{L} also has a first terminal, a second terminal, and a control terminal. The first terminal of the low-side power switching device SW_{L} is coupled to the second terminal of the high-side power switching device SW_{H} to form a common connection terminal SW, and the second terminal of the low-side power switching device SW_{L} is coupled to a reference ground GND. The high-side power switching device SW_{H} and the low-side power switching device SW_{L} are turned on and off based on switch driving signals (e.g., DR_{H} and DR_{L} in FIG. 1), causing energy storage components (e.g., an inductive energy storage device T, a resonant inductor Lr, and a resonant capacitor Cr shown in FIG. 1) to alternately store and release energy, thereby converting the input voltage V_{BUS} into an output voltage Vo to supply power to a load (not shown). In one example, the high-side power switching device SW_{H} and the low-side power switching device SW_{L} may each include a controllable transistor. For instance, the high-side power switching device SW_{H} and the low-side power switching device SW_{L} may each include a gallium nitride field-effect transistor (GaNFET).

In an embodiment, the control circuit 120 is configured to generate a high-side switching control signal S_{H} and a low-side switching control signal S_{L} for controlling the switching circuit. For example, the control circuit 120 may generate the high-side switching control signal S_{H} and the low-side switching control signal S_{L} based on a feedback signal being indicative of the output voltage Vo of the power conversion circuit 100. As shown in FIG. 1, the feedback signal is provided by a feedback circuit composed of resistors R1 and R2. For example, in an embodiment of a PWM control method such as voltage control and current control, the control circuit 120 may amplify the difference between the feedback signal and a reference signal, compare the amplified difference signal with a ramp signal, and generate the high-side switching control signal S_{H} and the low-side switching control signal S_{L}. It should be understood that the control circuit 120 may adopt any suitable control mode and circuit structure, provided that it enables control of the power conversion circuit 100—that is, it converts the input voltage V_{BUS} into the output voltage Vo by controlling the turn-on and turn-off switching of the switching circuit 110 (e.g., including the high-side power switching device SW_{H} and the low-side power switching device SW_{L}). The present application does not limit the topology or control mode of the control circuit 120.

In an embodiment, the high-side switching control signal S_{H} and the low-side switching control signal S_{L} are, for example, a pair of signals with opposite logic states, configured to control the high-side power switching device SW_{H} and the low-side power switching device SW_{L} to be alternately turn on and off, ensuring that only one power switching device is turned on at any specific time. In an embodiment, the high-side switching control signal S_{H} and the low-side switching control signal S_{L} are pulse-width modulation (PWM) signals.

In an embodiment, the bootstrap circuit 150 is shown in FIG. 1 as including a bootstrap diode D_{BST} and a bootstrap capacitor C_{BST}, connected in series between a bootstrap power supply input VCC and the common connection terminal SW of the low-side power switching device SW_{L} and the high-side power switching device SW_{H}. The bootstrap circuit 150 is configured to generate a bootstrap voltage V_{BST} using the voltage of the common connection terminal SW as a reference potential. The anode of the bootstrap diode D_{BST} is coupled to the bootstrap power supply input VCC to receive a bootstrap supply voltage, and the cathode of the bootstrap diode D_{BST} is coupled to a first terminal of the bootstrap capacitor C_{BST}. A second terminal of the bootstrap capacitor C_{BST} is coupled to the common connection terminal SW. When the high-side switch SW_{H} is turned off and the low-side switch SW_{L} is turned on, the voltage at the common connection terminal SW is zero, and the bootstrap supply voltage charges the bootstrap capacitor C_{BST} through the bootstrap diode D_{BST}. When the high-side switch SW_{H} is turned on and the low-side switch SW_{L} is turned off, the voltage at the common connection terminal SW becomes the input voltage V_{BUS}, and the voltage at the first terminal of the bootstrap capacitor C_{BST} is elevated to the input voltage V_{BUS} plus the bootstrap voltage V_{BST}. Simultaneously, the bootstrap diode D_{BST} is turned off due to reverse bias, thereby protecting the bootstrap power supply input VCC from damage caused by the relatively higher voltage. This elevated voltage enhances the driving capability of the high-side driving circuit 130, enabling better control of the turn-on and turn-off switching of the high-side power switching device SW_{H}. In an embodiment, the bootstrap voltage V_{BST} on the bootstrap capacitor C_{BST} also serves as the supply voltage for the high-side driving circuit 130.

In an embodiment, the high-side driving circuit 130 is configured to generate a high-side driving signal DR_{H} based on the high-side switching control signal S_{H}, and the low-side driving circuit 140 is configured to generate a low-side driving signal DR_{L} based on the low-side switching control signal S_{L}. The high-side driving circuit 130 and the low-side driving circuit 140 enhance the driving capability of the high-side switching control signal S_{H} and the low-side switching control signal S_{L}, respectively (i.e., increasing the amplitude difference between their logic high and low levels). Ideally, when the system is in a stable operation state, the output high-side driving signal DR_{H} and low-side driving signal DR_{L} are synchronized/consistent with the logic states of the high-side switching control signal S_{H} and low-side switching control signal S_{L}, respectively.

In an embodiment, the high-side driving circuit 130 is configured to receive the high-side switching control signal S_{H} and the bootstrap voltage V_{BST}, and generate the high-side driving signal DR_{H} based at least on these signals.

In the embodiment shown in FIG. 1, the power conversion circuit 100 may further include an inductive energy storage device T. For example, the inductive energy storage device T is shown in FIG. 1 as a transformer T including a primary winding Lp and a secondary winding Ls. The primary winding Lp is coupled between the common connection terminal SW of the low-side power switching device SW_{L} and the high-side power switching device SW_{H} and a primary-side reference ground GND of the power conversion circuit 100. The primary winding Lp may include an excitation inductance Lm. In an embodiment, the path from the common connection terminal SW to the primary-side reference ground GND via the primary winding Lp may further include a resonant capacitor Cr and a resonant inductor Lr connected in series. The secondary winding Ls of the inductive energy storage device T is coupled to rectifier diodes D1 and D2. The rectifier diodes D1 and D2 rectify the output of the secondary winding Ls of the transformer T, and a capacitor Co filters the output of the rectifier diodes D1 and D2.

It should be understood that the circuit shown in FIG. 1 is an example of how the inventive concept is applied to a power supply system. In the exemplary embodiment of FIG. 1, the power conversion circuit 100 adopts a half-bridge topology. However, the present invention is not limited to this configuration. For example, embodiments of the invention may also be applied to full-bridge topologies. Additionally, alternative embodiments may use inductors, or both inductors and transformers, in the power topology.

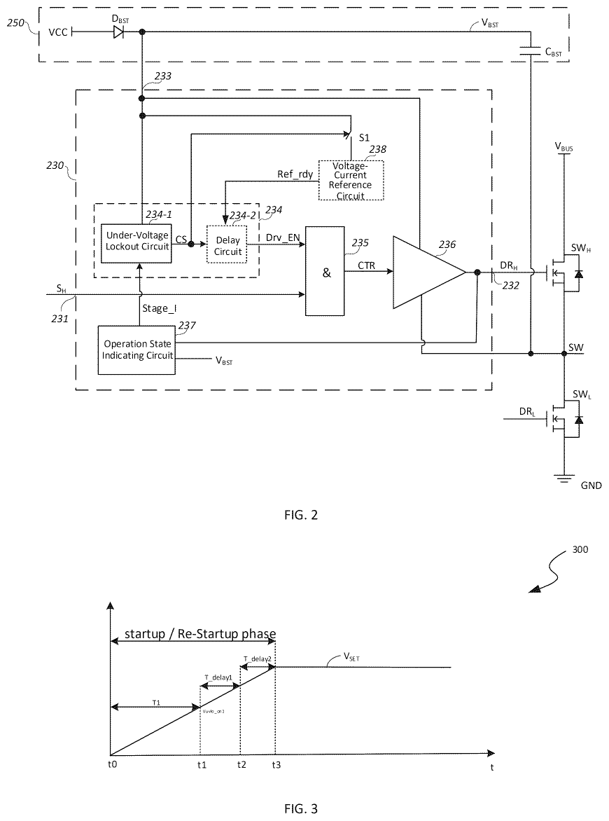

FIG. 2 illustrates a schematic block diagram of a high-side driving circuit 230 for driving a high-side power switching device SW_{H}, according to an embodiment of the present invention. The description of FIG. 2 will be combined with FIG. 1. The high-side driving circuit 230 is an implementation of the high-side driving circuit 130 shown in FIG. 1.

In the embodiment shown in FIG. 2, the high-side driving circuit 230 includes an input terminal 231 configured to receive a high-side switching control signal S_{H}, an output terminal 232 configured to output a high-side driving signal DR_{H}, a power supply terminal 233 configured to receive a bootstrap voltage V_{BST} from a bootstrap capacitor C_{BST}, a driving enable circuit 234, a logic circuit 235, a high-side driver 236, and an operation state indicating circuit 237.

In an embodiment, the operation state indicating circuit 237 is configured to:
receive the high-side driving signal DR_{H} and the bootstrap voltage V_{BST} from the bootstrap capacitor C_{BST}, determine an operation state of the high-side driving circuit 230 based on the high-side driving signal DR_{H} and the bootstrap voltage V_{BST}, and generate/provide an operation state indicating signal State_I indicating the operation state of the high-side driving circuit 230. For example, when it is detected that a number of logic high-level pulses of the high-side driving signal DR_{H} reaches a predetermined number PUL_NUM (e.g., 4), the operation state indicating circuit 237 generates the operation state indicating signal State_I in a set logic state (e.g., logic high), indicating that the high-side driving circuit 230 has entered a stable operation state. When it is detected that the bootstrap voltage V_{BST} is lower than a predetermined shutdown threshold V_{UVLO_down}, the operation state indicating signal State_I transitions from the set logic state (e.g., logic high) to a reset logic state (e.g., logic low), indicating that the high-side driving circuit 230 is in an abnormal state (e.g., insufficient supply voltage caused by a drop in the bootstrap voltage V_{BST}). In an embodiment, the predetermined number PUL_NUM and the shutdown threshold V_{UVLO_down} may be user-defined based on practical applications. For example, the predetermined number PUL_NUM and the predetermined shutdown threshold V_{UVLO_down} may be set by graphically using the interface (GUI).

In an embodiment, the driving enable circuit 234 is configured to generate a driving enable signal Drv_EN to enable or disable the driving of the high-side power switching device SW_{H} by the high-side driving circuit 230. Specifically, two input terminals of the logic circuit 235 receive the driving enable signal Drv_EN and the high-side switching control signal S_{H}, respectively, and output a driving control signal CTR at its output terminal. As shown in FIG. 2, the logic circuit 235 includes a logic AND circuit. When the driving enable signal Drv_EN is inactive (e.g., in the reset logic state, such as logic low), the logic circuit 235 outputs the driving control signal CTR in the reset logic state (e.g., logic low). The high-side driver 236 does not output the high-side driving signal DR_{H}, thereby controlling the high-side power switching device SW_{H} to remain off. In other words, the driving of the high-side power switching device SW_{H} by the high-side driving circuit 230 is disabled. When the driving enable signal Drv_EN is active (e.g., in the set logic state, such as logic high), the logic circuit 235 outputs the driving control signal CTR that is logically synchronized/consistent with the high-side switching control signal S_{H}. This driving control signal CTR is enhanced by the high-side driver 236 (i.e., increasing the amplitude difference between its logic high and low levels) to generate the high-side driving signal DR_{H}, which is synchronized/consistent with the logic state of the high-side switching control signal S_{H}, thereby controlling the high-side power switching device SW_{H} to be alternately turned on and off. That is, at this time, the driving of the high-side power switching device SW_{H} by the high-side driving circuit 230 is enabled.

During the startup or the initialization phase of the high-side driving circuit 230, the time for the driving enable signal Drv_EN to become active can be shortened, thereby reducing a duration between receiving the high-side switching control signal S_{H} and outputting the high-side driving signal DR_{H} to drive the high-side power switching device SW_{H}. This achieves rapid startup of the high-side driving circuit 230. The startup or initialization phase may refer to the process from when the high-side driving circuit 230 is activated/supplied with power (e.g., when the bootstrap voltage V_{BST} is first applied) until internal modules establish the necessary supply voltages and reference signals for normal operation. For example, activation may occur when the supply voltage (e.g., the bootstrap voltage V_{BST}) becomes higher than its under-voltage threshold.

As shown in FIG. 2, the driving enable circuit 234 includes an under-voltage lockout (UVLO) circuit 234-1. The UVLO circuit 234-1 compares the bootstrap voltage V_{BST} with under-voltage thresholds and generates an under-voltage protection signal CS to indicate whether to lock or activate the high-side driving circuit 230. The under-voltage protection signal CS serves as the driving enable signal Drv_EN to enable/disable the driving of the high-side power switching device SW_{H}. This protects the circuit by keeping the high-side power switching device SW_{H} turned off when the bootstrap voltage V_{BST} drops below the under-voltage threshold and is not refreshed (i.e., the bootstrap capacitor C_{BST} failed to be charged in time to restore the bootstrap voltage V_{BST} to above the under-voltage threshold), improving operational safety.

In an embodiment, the UVLO circuit 234-1 has a first operation mode and a second operation mode, and the UVLO circuit 234-1 is configured to generate the under-voltage protection signal CS based on different under-voltage thresholds in different operation modes. In an embodiment, when the UVLO circuit 234-1 is in the first operation mode, the UVLO circuit 234-1 is configured to generate the under-voltage protection signal CS based on the bootstrap voltage V_{BST} and the first under-voltage threshold value V_{UVLO1}. When the high-side driving circuit 230 is in the second operation state, the UVLO circuit 234-1 is configured to generate the under-voltage protection signal CS based on the bootstrap voltage V_{BST} and the second under-voltage threshold V_{UVLO2}. In an embodiment, the first under-voltage threshold V_{UVLO1} is smaller than the second under-voltage threshold V_{UVLO2}.

In an embodiment, the high-side driving circuit 230 is configured to: in the startup stage or initialization stage of the high-side driving circuit 230, output the high-side driving signal DR_{H} after a delay period T_delay has elapsed since the bootstrap voltage V_{BST} reaches or exceeds the first under-voltage threshold V_{UVLO1}; and in the stable operation state of the high-side driving circuit 230, stop outputting the high-side driving signal DR_{H} in response to the bootstrap voltage V_{BST} becoming lower than the second under-voltage threshold V_{UVLO2}.

In an embodiment, the delay period T_delay includes intrinsic delays of the UVLO circuit 234-1, such as a first delay period T_delay1 from a time when the bootstrap voltage V_{BST} reaches or exceeds the first under-voltage threshold V_{UVLO1} to a time when the UVLO circuit 234-1 transitioning the under-voltage protection signal CS from the reset logic state (e.g., logic low) to the set logic state (e.g., logic high).

In one embodiment, when the bootstrap voltage V_{BST} becomes lower than the shutdown threshold V_{UVLO_down}, the under-voltage lockout circuit 234-1 switches to the first operation mode. In one embodiment, when the number of the logic high-level pulses of the high-side driving signal D_{RH} output by the high-side driving circuit 230 reaches the predetermined number PUL_NUM (for example, 4), the voltage lockout circuit 234-1 switches to the second operation mode. In one embodiment, the shutdown threshold V_{UVLO_down} is lower than or equal to the first under-voltage threshold V_{UVLO1}. For example, when the number of the logic high-level pulses of the high-side driving signal D_{RH} output by the high-side driving circuit 230 reaches the predetermined number of PUL_NUM (for example, 4), the operation state indicating circuit 237 changes the operation state indicating signal State_I from a reset logic state (for example, logic low) to a set logic state (for example, logic high), indicating that the high-side driving circuit 230 enters a stable operation state, at which time the under-voltage lockout circuit 234-1 switches to the second operation mode based on the operation state indicating signal State_I in the set logic state (e.g., logic high). When the bootstrap voltage V_{BST} becomes lower than the shutdown threshold V_{UVLO_down}, the operation state indicating circuit 237 changes the operation state indicating signal State_I from the set logic state (e.g., logic high) to the reset logic state (e.g., logic low), indicating that the high-side driving circuit 230 enters an abnormal state, and at this time, the under-voltage lockout circuit 234-1 switches to the first operation mode based on the operation state indicating signal State_I in the reset logic state (e.g., logic low).

In one embodiment, the under-voltage lockout circuit 234-1 includes a hysteresis comparator configured to perform a hysteresis comparison between the bootstrap voltage V_{BST} and the under-voltage threshold V_{UVLO} and generate the under-voltage protection signal CS based on the comparison result. In this embodiment, the first under-voltage threshold V_{UVLO1} includes a first under-voltage lockout threshold V_{UVLO_off1} and a first under-voltage recovery threshold V_{UVLO_on1}, and the second under-voltage threshold V_{UVLO2} includes a second under-voltage lockout threshold V_{UVLO_off2} and a second under-voltage recovery threshold V_{UVLO_on2}. The first under-voltage lockout threshold V_{UVLO_off1} and the first under-voltage recovery threshold V_{UVLO_on1} are smaller than the corresponding second under-voltage lockout threshold V_{UVLO_off2} and second under-voltage recovery threshold V_{UVLO_on2}, respectively. The first under-voltage recovery threshold V_{UVLO_on1} and the first under-voltage lockout threshold V_{UVLO_off1}, and the second under-voltage recovery threshold V_{UVLO_on2} and the second under-voltage lockout threshold V_{UVLO_off2} are two pairs of voltages that are set to have a small difference, to avoid mis-operations caused by ripples. For example, in an application example, the first under-voltage recovery threshold V_{UVLO_on1}=6.2 V, the first under-voltage lockout threshold V_{UVLO_off2}=6 V, and the difference voltage between the two is 0.2 V. The second under-voltage recovery threshold V_{UVLO_on1}=9V, the second under-voltage lockout threshold V_{UVLO_off2}=8.5 V, and the difference voltage between the two is 0.5 V. The shutdown threshold V_{UVLO_down} is 4.5 V.

In one embodiment, the high-side driving circuit 230 is configured to: in the startup phase or the initialization phase of the high-side driving circuit 230, output the high-side driving signal DR_{H} after the delay period T_delay has elapsed since the bootstrap voltage V_{BST} reaches or exceeds the first under-voltage recovery threshold V_{UVLO_on1}; and during the stable operation state of the high-side driving circuit 230, stop outputting the high-side driving signal DR_{H} in response to the bootstrap voltage V_{BST} becoming lower than the second under-voltage lockout threshold V_{UVLO_off2}.

It should be understood that the first under-voltage lockout threshold V_{UVLO_off1} and the first under-voltage recovery threshold V_{UVLO_on1} and the corresponding second under-voltage lockout threshold V_{UVLO_off2} and second under-voltage recovery threshold V_{UVLO_on2} may be determined based on the conduction characteristics of the high-side power switching device SW_{H} and its power configuration (such as the resonant inductance and capacitance of the LLC).

In an embodiment, the driving enable circuit 234 further includes a delay circuit 234-2 (for example, shown as a dashed box in FIG. 2). The delay circuit 234-2 generates a driving enable signal Drv_EN by delaying the under-voltage protection signal CS generated by the under-voltage lockout circuit 234-1. In one embodiment, the delay circuit 234-2 is configured to trigger the driving enable signal Drv_EN to transition from a reset logic state (e.g., logic low) to a set logic state (e.g., logic high) after a second delay period T_delay2 has elapsed since a transition edge of the under-voltage protection signal CS from the reset logic state (e.g., logic low) to the set logic state (e.g., logic high).

In an embodiment, the high-side driving circuit 230 may further include a voltage-current reference circuit 238 (for example, shown as a dashed box in FIG. 2), coupled between the bootstrap capacitor C_{BST} and the delay circuit 234-2, and configured to provide a reference signal (for example, a reference current and/or voltage) required for normal operations of other circuits inside the high-side driving circuit 230. In one embodiment, the second delay period T_delay2 includes a time duration for the voltage-current reference circuit 238 to establish the reference signal. For example, to ensure reliable and stable turn-on of the high-side switch transistor SW_{H}, the high-side driver 236 may further include a clamping circuit (not shown). The clamping circuit is powered by the bootstrap capacitor C_{BST} to clamp the high-side driving signal DR_{H} at a preset fixed voltage. For example, the clamping circuit may clamp the high-side driving signal DR_{H} at the fixed voltage based on the reference voltage generated by the voltage-current reference circuit 238.

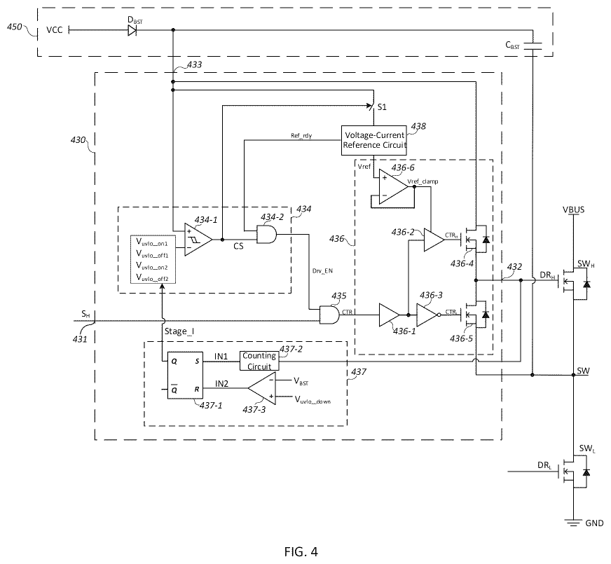

In the startup phase or initialization phase of the high-side driving circuit 230, when the under-voltage lockout circuit 234-1 outputs the under-voltage protection signal CS in the set logic state (e.g., logic high), indicating the high-side driving circuit 230 is to exit the under-voltage lockout state. At this time, the under-voltage protection signal CS turns on the switch S1 to connect the voltage-current reference circuit 238 to the bootstrap capacitor C_{BST}, so that the voltage-current reference circuit 238 can start to establish the reference voltage/current required by other circuits (e.g., the above-mentioned clamping circuit) inside the high-side driving circuit 230 based on the bootstrap voltage V_{BST}. After the reference information such as the internal reference voltage or current is established, the startup process of the high-side driving circuit 230 is completed, and an indication signal Vref_rdy indicating that the reference voltage and/or current is established successfully is output to the delay circuit 234-2. In one embodiment, the delay circuit 234-2 starts to output the delayed under-voltage protection signal as the driving enable signal Dr_EN based on the indication signal Vref_rdy. For example, the delay circuit 234-2 may set the driving enable signal Dr_EN to active (i.e., a set logic state (e.g., logic high)) based on the indication signal Vref_rdy, indicating that the high-side driving circuit 230 is ready to output the high-side driving signal DR_{H} to drive the power switching device SW_{H}. In this embodiment, as shown in FIG. 3, the startup phase or the initialization phase of the high-side driving circuit 230 may be divided into three periods: a first period T1(e.g., t0˜t1) for charging the bootstrap voltage V_{BST} on the bootstrap capacitor C_{BST} from an initial voltage (e.g., 0V) lower than the first under-voltage recovery threshold V_{UVLO_on1} to a voltage higher than the first under-voltage recovery threshold V_{UVLO_on1}, a first delay period T_delay1(e.g., t1˜t2) from a time when the bootstrap voltage V_{BST} becoming higher than the first under-voltage recovery threshold V_{UVLO_on1} to a time when the under-voltage lockout circuit 234-1 outputs the under-voltage protection signal CS with the set logic state (e.g., logic high), and a second delay period T_delay2 (e.g., t2˜t3) for the voltage-current reference circuit 238 to establish the reference information required by other internal circuits based on the bootstrap voltage V_{BST}.

In one embodiment, the high-side driver 236 is coupled between the bootstrap capacitor C_{BST} and a control terminal of the high-side power switching device SW_{H}, and is configured to enhance the driving control signal CTR (i.e., increase an amplitude difference between the logic high level and the logic low level of the driving control signal CTR) to generate the high-side driving signal DR_{H}. The maximum value of the high-side driving signal DR_{H} is related to the bootstrap voltage V_{BST}, e.g., equal to the bootstrap voltage V_{BST}, or equal to the bootstrap voltage V_{BST} minus a voltage threshold.

According to an embodiment of the present invention, by setting the first under-voltage threshold V_{UVLO1} (e.g., including the first under-voltage lockout threshold V_{UVLO_off1} and the first under-voltage recovery threshold V_{UVLO_on1}) to be lower than the corresponding second under-voltage threshold V_{UVLO2} (e.g., including the second under-voltage lockout threshold V_{UVLO_off2} and the second under-voltage recovery threshold V_{UVLO_on2}), the duration for which the driving enable signal Dr_EN becomes active in the startup phase or the initialization phase can be reduced. Specifically, by setting the under-voltage threshold of the startup phase or the initialization phase to be lower than the under-voltage threshold of the stable operation state, the high-side driving circuit 230 may be controlled to exit the locked state in advance in the startup phase or the initialization phase, so as to provide the power supply (e.g., the bootstrap voltage V BST) to the voltage-current reference circuit 238 in advance, so that the preparation operation (e.g., generating the reference voltage and/or current) for the internal circuits of the high-side driving circuit 230 may be performed in advance. On the other hand, during the preparation operations of the internal circuits, the bootstrap capacitor C_{BST} remains continuously charged so that the bootstrap voltage V_{BST} can rise to an acceptable voltage level after the startup preparation of the high-side driving circuit 230 is completed. In this way, the startup speed of the high-side driving circuit 230 is improved, while the turn-on reliability of the high-side switch SW_{H} can be ensured, thereby ensuring the safe and fast operation of the switching power supply.

It should be understood that, in actual operation, although the bootstrap capacitor C_{BST} continues to be charged during the process of establishing the reference signal (e.g., the reference voltage and/or current) by the voltage-current reference circuit 238, the bootstrap capacitor C_{BST} may not be fully charged to the voltage for normal operation (e.g., the predetermined voltage V_{SET} shown in FIG. 3) until the voltage-current reference circuit 238 sends the indication signal Vref_rdy indicating that the establishment of the reference voltage is completed. However, since the energy in the energy storage elements (for example, the inductive energy storage device T, the inductor Lr, and the capacitor Cr shown in FIG. 1) is in a stage of gradually accumulating in the first several switching cycles when the power conversion system is starting, the average value of the loop current is at a lower level, and even if the voltage of the high-side driving signal DR_{H} is slightly lower than the voltage for normal operation, the high-side switching transistor SW_{H} can be driven without causing a large conduction loss. In the embodiment of the present disclosure, by setting the under-voltage threshold in the startup phase or the initialization phase to be lower than the under-voltage threshold in the stable operation state, the high-side driving circuit 230 is controlled to exit the locked state in advance in the startup phase or the initialization phase, so that the reference information such as the reference voltage or the reference current required for internal normal operation can be established synchronously in the process of charging the bootstrap voltage C_{BST}, thereby not only improving the startup speed of the high-side driving circuit 230, but also ensuring the turn-on reliability of the high-side switch SW_{H}, so as to ensure the safe and fast operation of the switching power supply.

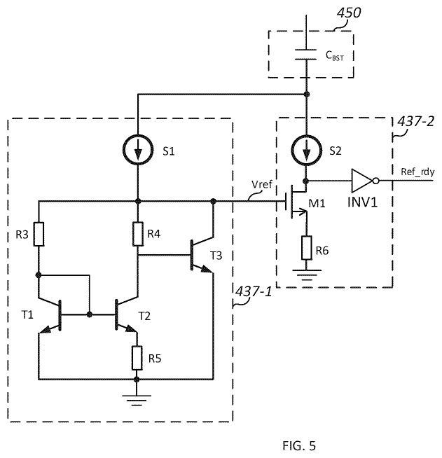

FIG. 4 shows a schematic circuit diagram of a high-side driving circuit 430 for driving a high-side power switching device according to an embodiment of the present invention. This high-side driving circuit 430 is one exemplary implementation of the aforementioned high-side driving circuits 130 and 230. FIG. 4 is described in combination with FIGS. 1-3.

In the embodiment shown in FIG. 4, the high-side driving circuit 430 includes an input terminal 431 for receiving the high-side switching control signal S_{H}, an output terminal 432 for outputting the high-side driving signal DR_{H}, a power supply terminal 433 for receiving the bootstrap voltage V_{BST} from the bootstrap capacitor C_{BST}, a driving enable circuit 434, a logic AND circuit 435, a high-side driver 436, an operation state indicating circuit 437, and a voltage-current reference circuit 438. The connection relationship is shown in FIG. 4.

In the embodiment shown in FIG. 4, the high-side driver 436 includes buffers 436-1 and 436-2, an inverter 436-3, and switches 436-4 and 436-5. As shown in FIG. 4, switches 436-4 and 436-5 are coupled in series between bootstrap voltage V_{BST} and a drain of power switching device SW_{H}. The driving control signal CTR is buffered and enhanced by the buffers 436-1 and 436-2 to generate the driving control signal CTR_{H} for controlling the switch 436-4. The driving control signal CTR is buffered by the buffer 436-1 and inverted by the inverter 436-3 to generate the driving control signal CTR_{L} for controlling the switch 436-5. Under the control of the driving control signals CTR_{H} and CTR_{L}, the switches 436-4 and 436-5 are alternately turned on and off, thereby providing a high-side driving signal DR_{H} at the common terminal of the switches 436-4 and 436-5.

According to an embodiment of this application, as shown in FIG. 4, the high-side driver 436 further includes a clamping circuit 436-6. The clamping circuit 436-6 is configured to clamp the high-side driving signal DR_{H} at a fixed voltage Vref_clamp, so that the high-side switching transistor SW_{H} is reliably and stably turned on. As shown in FIG. 4, the clamping circuit 436-6 generates the fixed voltage Vref_clamp based on a reference voltage Vref received from the voltage-current reference circuit 438. Those skilled in the art should understand that the specific circuits of the high-side driver 436 and the clamping circuit 436-6 shown in FIG. 4 are merely provided as examples, and the present disclosure is not limited thereto.

As shown in FIG. 4, the operation state indicating circuit 437 includes a latch 437-1, a counting circuit 437-2 and a comparator 437-3. The counting circuit 437-2 includes an input terminal for receiving the high-side driving signal DR_{H} from the output terminal 432 and an output terminal. The counting circuit 437-2 is configured to count a number of logic high-level pulses of the high-side driving signal DR_{H}, and generate a first indication signal IN1 according to a counting result. When the number of logic high-level pulses reaches the predetermined number PUL_NUM (e.g., 4), the counting circuit 437-2 changes the first indication signal IN1 from a reset logic state (e.g., logic low) to a set logic state (e.g., logic high). In an exemplary embodiment, the counting circuit 437-2 starts counting in response to the bootstrap voltage V_{BST} becoming higher than a first under-voltage threshold (e.g., a first voltage recovery threshold V_{UVLO_on1}). In an embodiment, the counting circuit 437-2 includes a voltage sampling circuit configured to sample a rising edge of the high-side driving signal DR_{H}, and when a rising edge is sampled, the counting circuit 437-2 increases the number of logic high-level pulses by 1. In one embodiment, in response to the bootstrap voltage V_{BST} being lower than, for example, the second under-voltage lockout threshold V_{UVLO_off2}, the counting circuit 437-2 resets the number of logic high-level pulses and sets the first indication signal IN1 to the reset logic state (e.g., logic low). The comparator 437-3 includes a first input terminal (e.g., an inverting input), a second input terminal (e.g., a non-inverting input), and an output terminal, where the first input terminal is coupled to the bootstrap capacitor C_{BST} and configured to receive the bootstrap voltage V_{BST}, and the second input terminal is configured to receive the shutdown threshold V_{UVLO_down}. The comparator 437-3 is configured to compare the bootstrap voltage V_{BST} with the shutdown threshold V_{UVLO_down}, and generate a second indication signal IN2 at the output terminal according to the comparison result. For example, when the bootstrap voltage V_{BST} becomes lower than the shutdown threshold V_{UVLO_down}, the second indication signal IN2 output by the comparator 437-3 changes from the reset logic state (e.g., logic low) to the set logic state (e.g., logic high). A set terminal S of the latch 437-1 is controlled by the first indication signal IN1, and a reset terminal R is controlled by the second indication signal IN2. When the first indication signal IN1 changes from the reset logic state (e.g., logic low) to the set logic state (e.g., logic high), the operation state indicating signal State_I output by the latch 437-1 changes from the reset logic state (e.g., logic low) to the set logic state (e.g., logic high), indicating that the high-side driving circuit 430 enters the stable operation state. When the second indication signal IN2 changes from the reset logic state (e.g., logic low) to the set logic state (e.g., logic high), the operation state indicating signal State_I output by the latch 437-1 changes from the set logic state (e.g., logic high) to the reset logic state (e.g., logic low), indicating that the high-side driving circuit 430 enters an abnormal operation state.

In one embodiment, the under-voltage lockout circuit 434-1 switches the operation modes based on the operation state indicating signal State_I. For example, when the operation state indicating signal State_I changes from the reset logic state (e.g., logic low) to the set logic state (e.g., logic high), the under-voltage lockout circuit 434 switches to the second operation mode, and when the operation state indicating signal State_I changes from the set logic state (e.g., logic high) to the reset logic state (e.g., logic low), the under-voltage lockout circuit 434 switches to the first operation mode. As described above, in the first operation mode, the under-voltage lockout circuit 434-1 has the first under-voltage threshold V_{UVLO1} (e.g., including the first under-voltage lockout threshold V_{UVLO_off1} and the first under-voltage recovery threshold V_{UVLO_on1}), and in the second operation mode, the under-voltage lockout circuit 434-1 has the second under-voltage threshold V_{UVLO2} (e.g., including the second under-voltage lockout threshold V_{UVLO_off2} and the second under-voltage recovery threshold V_{UVLO_on2}).

In one embodiment, as shown in FIG. 4, the under-voltage lockout circuit 434-1 includes a hysteresis comparator which includes a first input terminal (e.g., a non-inverting input) for receiving the bootstrap voltage V_{BST}, a second input terminal (e.g., an inverting input) for receiving the under-voltage lockout threshold and the under-voltage recovery threshold, and an output terminal. For example, in response to the operation state indicating signal State_I changing from the set logic state (e.g., logic high) to the reset logic state (e.g., logic low), the under-voltage lockout circuit 434-1 switches to the first operation mode, and at this time, the second input terminal of the hysteresis comparator is configured to receive the first under-voltage lockout threshold V_{UVLO_off1} and the first under-voltage recovery threshold V_{UVLO_on1}. In response to the operation state indicating signal State_I changing from the reset logic state (e.g., logic low) to the set logic state (e.g., logic high), the under-voltage lockout circuit 434-1 switches to the second operation mode, and the second input terminal of the hysteresis comparator is configured to receive the second under-voltage lockout threshold V_{UVLO_off2} and the second under-voltage recovery threshold V_{UVLO_on2}. As described above, the first under-voltage lockout threshold V_{UVLO_off1} and the first under-voltage recovery threshold V_{UVLO_on1} are lower than the corresponding second under-voltage lockout threshold V_{UVLO_off2} and second under-voltage recovery threshold V_{UVLO_on2}, respectively.

In the startup phase or initialization phase of the high-side driving circuit 430, the low-side power switching device SW_{L} is turned on first, and the high-side power switching device SW_{H} remains off because sufficient supply voltage and reference current/voltage have not yet been established. The bootstrap capacitor C_{BST} is charged by the low-side power switching device SW_{L}, and the bootstrap voltage V_{BST} is gradually increased. When the bootstrap voltage V_{BST} rises to be greater than the first under-voltage recovery threshold V_{UVLO_on1}, the under-voltage protection signal CS output by the under-voltage lockout circuit 434-1 changes from the reset logic state (e.g., logic low) to the set logic state (e.g., logic high), indicating that the high-side driving circuit 430 exits the lockout state. The under-voltage protection signal CS in the set logic state (e.g., logic high) turns on the switch S1, thereby connecting the voltage-current reference circuit 438 to the bootstrap voltage V_{BST}. The voltage-current reference circuit 438 starts to establish the reference voltage and/or current (e.g., shown as the reference voltage Vref in FIG. 4) required by other internal circuits (e.g., the clamping circuit 436-6) based on the bootstrap voltage V_{BST}, and generates an indication signal Vref_rdy for indicating that the reference voltage and/or current is successfully established. When the reference voltage and/or current establishment is complete, the indication signal Vref_rdy changes to a set logic state (e.g., logic high).

FIG. 5 shows an exemplary circuit diagram of a voltage-current reference circuit 438 according to an embodiment of the present invention. Referring to FIG. 5, the voltage-current reference circuit 438 may include a reference voltage generating circuit 438-1 and a reference signal indication circuit 438-2. The connection relationship is shown in FIG. 5.

In the example shown in FIG. 5, the reference voltage generating circuit 438-1 is shown to include a bandgap reference circuit including a resistor R3-R5, a triode T1-T3, and a current source S1. The bandgap reference circuit 438-1 generates the reference voltage Vref based on the bootstrap voltage V_{BST} received from the bootstrap capacitor C_{BST}. The principle of how the bandgap reference circuit 438-1 operates to generate the reference voltage Vref is well known to those skilled in the art, and will not be repeated here. The reference signal indication circuit 438-2 includes a switch M1, a current source S2 and an inverter INV1. After the reference voltage Vref is successfully established, the switch M1 may be controlled to be turned on, thereby generating the indication information Ref_rdy in the set logic state (e.g., logic high).

It should be understood that the circuit structure shown in FIG. 5 is only one example of the voltage-current reference circuit 438. For example, those skilled in the art may take any suitable circuit structure to generate the reference voltage, and may take any suitable circuit structure to generate an indication signal for indicating that the reference voltage has been successfully established.

Referring back to FIG. 4, when the voltage-current reference circuit 438 generates the indication signal Ref_rdy in the set logic state (e.g., logic high), it indicates that the start process of the high-side driving circuit 430 has completed. The logic AND circuit 435 outputs the driving control signal CTR that is synchronized with/consistent with the logic state of the high-side switching control signal S_{H}, and after the driving control signal CTR is enhanced by the high-side driver 436, a high-side driving signal DR_{H} that is also synchronized with/consistent with the logic state of the high-side switching control signal S_{H} is generated, thereby starting to control the turn-on and turn-off switching of the high-side power switching device SW_{H}.

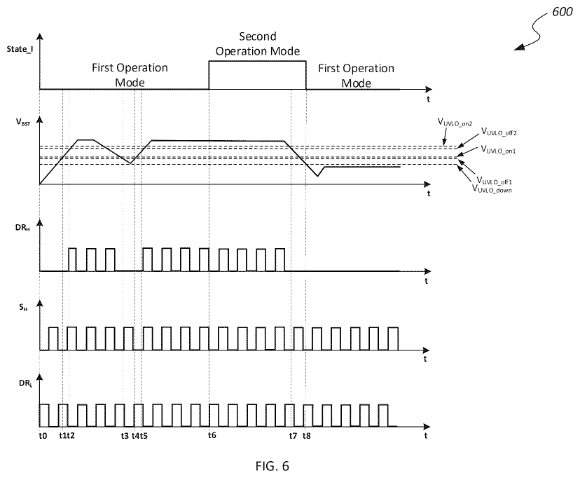

FIG. 6 shows a waveform diagram of some signals generated during the operation of the high-side driving circuit 430 according to an embodiment of the present disclosure.

At time t0, the low-side power switching device SW_{L} is turned on under the control of the low-side driving signal DR_{L}, the bootstrap capacitor C_{BST} starts to charge, and the bootstrap voltage V_{BST} on the bootstrap capacitor C_{BST} gradually increases. The operation state indicating signal State_I is at logic low, and the under-voltage lockout circuit 434-1 is in the first operation mode, i.e., having the first under-voltage lockout threshold V_{UVLO_off1} and the first under-voltage recovery threshold V_{UVLO_on1}.

At time t1, the bootstrap voltage V_{BST} increases to the first under-voltage recovery threshold V_{UVLO_on1}, and at this time, the high-side driving circuit 430 exits the locked state. After a short delay (for example, the aforementioned delay period T_delay1 and delay period T_delay2), the high-side driving signal DR_{H} synchronized/consistent with the logic state of the high-side switching control signal S_{H} starts to be output at time t2.

Until time t3, the bootstrap voltage V_{BST} drops below the first under-voltage lockout threshold V_{UVLO_off1}, the high-side driving circuit 430 is locked again, and stops outputting the high-side driving signal DR_{H}. Since the number of logic high-level pulses of the high-side driving signal DR_{H} is less than the predetermined number PUL_NUM (e.g., 4) between time t2 and time t3, the operation state indicating signal State_I is still at logic low, indicating that the high-side driving circuit 430 has not entered the stable operation state, and the under-voltage lockout circuit 434-1 remains in the first operation mode.

Subsequently, at time t4, the bootstrap voltage V_{BST} rises above the first under-voltage recovery threshold V_{UVLO_on1} again, and at this time, the high-side driving circuit 430 is activated again, and after a short delay (e.g., the aforementioned delay period T_delay1 and delay period T_delay2), starts to output the high-side driving signal DR_{H} synchronized/consistent with the logic state of the high-side switching control signal S_{H} at time t5.

At time t6, the number of logic high-level pulses of the high-side driving signal DR_{H} reaches the predetermined number PUL_NUM (e.g., 4), and at this time, the operation state indicating signal State_I becomes logic high, indicating that the high-side driving circuit 430 enters the stable operation state, and the under-voltage lockout circuit 434-1 switches to the second operation mode. In the second operation mode, the under-voltage lockout circuit 434-1 has the second under-voltage lockout threshold V_{UVLO_off2} and the second under-voltage recovery threshold V_{UVLO_on2}.

At time t7, the bootstrap voltage V_{BST} drops below the second under-voltage lockout threshold V_{UVLO_off2}, the high-side driving circuit 430 is locked and no longer outputs the high-side driving signal DR_{H}.

Subsequently, the bootstrap voltage V_{BST} continues to drop and becomes lower than the shutdown threshold V_{UVLO_}down at time t8. At this time, the operation state indicating signal State_I becomes logic low, indicating that the high-side driving circuit 430 enters the abnormal operation state, and the under-voltage lockout circuit 434-1 switches to the first operation mode.

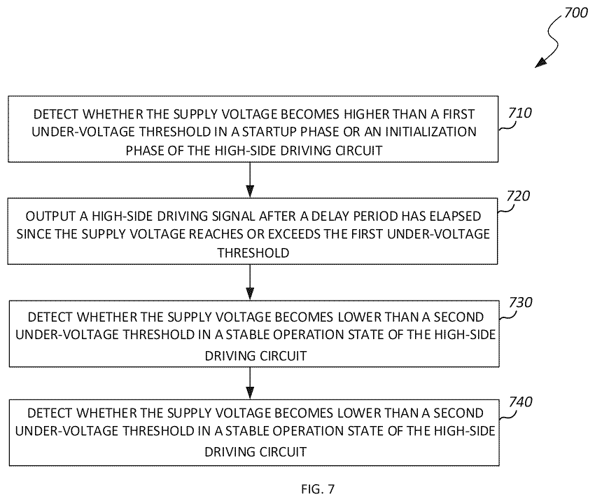

FIG. 7 shows a flowchart of a method 700 of operating a high-side driving circuit (e.g., 130, 230 or 430) according to an embodiment of the present invention. FIG. 7 may be described in conjunction with FIGS. 1, 2, and 4. The high-side driving circuit may be supplied with a supply voltage by a bootstrap capacitor (e.g., C_{BST}) and used to drive a high-side power switching device (e.g., SW_{H}). The high-side driving circuit includes an under-voltage lockout circuit (e.g., 234-1 or 434-1) to generate an under-voltage protection signal to control lockout and activation of the high-side driving circuit. The method 700 may include the following steps:
Step 710: detecting whether the supply voltage becomes higher than a first under-voltage threshold in a startup phase or an initialization phase of the high-side driving circuit.
Step 720: outputting a high-side driving signal after a delay period has elapsed since the supply voltage reaches or exceeds the first under-voltage threshold.
Step 730: detecting whether the supply voltage becomes lower than a second under-voltage threshold in a stable operation state of the high-side driving circuit.
Step 740: stopping outputting the high-side driving signal when the supply voltage becomes lower than the second under-voltage threshold.

In one embodiment, the first under-voltage threshold is lower than the second under-voltage threshold.

In one embodiment, the under-voltage lockout circuit enters a first operation mode when the bootstrap voltage becomes lower than a shutdown threshold. In one embodiment, the under-voltage lockout circuit enters a second operation mode when the high-side driving circuit outputs a high-side driving signal with a predetermined number of consecutive logic high-level pulses. In one embodiment, the shutdown threshold is lower than or equal to the first under-voltage threshold.

The foregoing detailed description and drawings are merely illustrative of common embodiments of the invention. It will be apparent that various additions, modifications and substitutions are possible without departing from the spirit and scope of the invention as defined by the claims. Those skilled in the art will appreciate that the present invention may vary in form, structure, layout, proportions, materials, elements, components, and other aspects depending on the specific environment and operating requirements in a practical application without departing from the principles of the invention. Accordingly, the embodiments disclosed herein are meant to be illustrative only and not limiting as to the scope of the invention which is to be defined by the appended claims and their legal equivalents and not limited by the foregoing description.

1. A high-side driving circuit for driving a high-side power switching device, comprising:
an input terminal, configured to receive a high-side switching control signal;
an output terminal, coupled to a control terminal of the high-side power switching device and configured to provide a high-side driving signal to control turn-on and turn-off switching of the high-side power switching device; and
a power supply terminal, configured to receive a bootstrap voltage;
wherein the high-side driving circuit is configured to: in a startup phase or an initialization phase of the high-side driving circuit, output the high-side driving signal after a delay period has elapsed since the bootstrap voltage reaches or exceeds a first under-voltage threshold; and in a stable operation state of the high-side driving circuit, stop outputting the high-side driving signal in response to the bootstrap voltage becoming lower than a second under-voltage threshold, wherein the first under-voltage threshold is lower than the second under-voltage threshold.

2. The high-side driving circuit of claim 1, further comprising:
an under-voltage lockout circuit configured to generate an under-voltage protection signal to control lockout and activation of the high-side driving circuit, wherein the under-voltage lockout circuit has a first operation mode and a second operation mode.

3. The high-side driving circuit of claim 2, wherein the delay period comprises:
a first delay period from a time when the bootstrap voltage becomes higher than the first under-voltage threshold to a time when the under-voltage lockout circuit outputs an under-voltage protection signal having a set logic state.

4. The high-side driving circuit according to claim 2, wherein when the under-voltage lockout circuit is in the first operation mode, the under-voltage lockout circuit is configured to generate the under-voltage protection signal based on the bootstrap voltage and the first under-voltage threshold; and wherein when the under-voltage lockout circuit is in the second operation mode, the under-voltage lockout circuit is configured to generate the under-voltage protection signal based on the bootstrap voltage and the second under-voltage threshold.

5. The high-side driving circuit according to claim 4, wherein
the under-voltage lockout circuit comprises a hysteresis comparator having a first input terminal, a second input terminal, and an output terminal, and wherein the first under-voltage threshold comprises a first under-voltage lockout threshold and a first under-voltage recovery threshold greater than the first under-voltage lockout threshold, the second under-voltage threshold comprises a second under-voltage lockout threshold and a second under-voltage recovery threshold greater than the second under-voltage lockout threshold, and wherein
when the under-voltage lockout circuit is in the first operation mode, a first input terminal of the hysteresis comparator is configured to receive the bootstrap voltage, a second input terminal of the hysteresis comparator is configured to receive the first under-voltage lockout threshold and the first under-voltage recovery threshold, when the bootstrap voltage is lower than the first under-voltage lockout threshold, the hysteresis comparator outputs the under-voltage protection signal having a reset logic state at its output terminal, and when the bootstrap voltage is higher than the first under-voltage recovery threshold, the hysteresis comparator outputs the under-voltage protection signal having a set logic state at its output terminal; and
when the under-voltage lockout circuit is in the second operation mode, the first input terminal of the hysteresis comparator is configured to receive the bootstrap voltage, the second input terminal of the hysteresis comparator is configured to receive the second under-voltage lockout threshold and the second under-voltage recovery threshold, and when the bootstrap voltage is lower than the second under-voltage lockout threshold, the hysteresis comparator outputs the under-voltage protection signal with the reset logic state at its output terminal, and when the bootstrap voltage is higher than the second under-voltage recovery threshold, the hysteresis comparator outputs the under-voltage protection signal with the set logic state at its output terminal.

6. The high-side driving circuit of claim 2, wherein the under-voltage lockout circuit switches to the first operation mode when the bootstrap voltage becomes lower than a shutdown threshold, wherein the shutdown threshold is lower than or equal to the first under-voltage threshold.

7. The high-side driving circuit of claim 2, wherein the under-voltage lockout circuit switches to the second operation mode when a number of logic high-level pulses of the high-side driving signal output by the high-side driving circuit reaches a predetermined number.

8. The high-side driving circuit of claim 2, further comprising:
an operation state indicating circuit configured to receive the high-side driving signal and the bootstrap voltage to generate an operation state indicating signal for indicating an operation state of the driving circuit,
wherein when the operation state indicating circuit detects that the bootstrap voltage is lower than the shutdown threshold, the operation state indicating circuit outputs the operation state indicating signal with a reset logic state; when the operation state indicating circuit detects that a number of the logic high-level pulses of the high-side driving signal reaches a predetermined number, the operation state indicating circuit outputs the operation state indicating signal with a set logic state.

9. The high-side driving circuit according to claim 8, wherein the under-voltage lockout circuit enters the first operation mode in response to an operation state indicating signal with the reset logic state, and enters the second operation mode in response to the operation state indicating signal with the set logic state.

10. The high-side driving circuit according to claim 8, wherein the operation state indicating circuit comprises:
a counting circuit, configured to count consecutive logic high-level pulses of the high-side driving signal to generate a count indication signal;
a comparator, configured to compare the bootstrap voltage with the shutdown threshold to generate a comparison signal; and
a latch, wherein a set terminal of the latch is controlled by the count indication signal, a reset terminal of the latch is controlled by the comparison signal, and the latch generates the operation state indicating signal based on the count indication signal and the comparison signal.

11. The high-side driving circuit according to claim 2, configured to generate a driving enable signal based on the bootstrap voltage, wherein when the driving enable signal is invalid, the high-side driving circuit controls the high-side power switching device to remain off, and when the driving enable signal is valid, the high-side driving circuit outputs the high-side driving signal to control the high-side power switching device to be alternately turned on and off.

12. The high-side driving circuit of claim 11, further comprising:
a delay circuit coupled to an output terminal of the under-voltage lockout circuit to receive the under-voltage protection signal and configured to generate the driving enable signal based on the under-voltage protection signal,
wherein the delay circuit is further configured to, in response to a transition edge of the under-voltage protection signal transitioning from a reset logic state to a set logic state, trigger the driving enable signal to correspondingly transit from a reset logic state to a set logic state after a second delay period.

13. The high-side driving circuit of claim 12, wherein the delay period comprises the second delay period.

14. The high-side driving circuit according to claim 12, further comprising a voltage-current reference circuit, wherein the voltage-current reference circuit is configured to start to establish a reference signal based on the bootstrap voltage in response to a transition edge of the under-voltage protection signal transiting from the reset logic state to the set logic state, and output an indication information indicating that the reference signal is successfully established after the reference signal is successfully established, wherein the second delay period comprises a duration for which the voltage-current reference circuit establishes the reference signal.

15. The high-side driving circuit of claim 14, wherein the voltage-current reference circuit comprises a bandgap reference circuit.

16. The high-side driving circuit according to claim 14, wherein the delay circuit comprises a logic AND circuit having a first input terminal, a second input terminal and an output terminal, wherein the first input terminal is configured to receive the under-voltage protection signal, the second input terminal is configured to receive the indication information, and the output terminal is configured to output the driving enable signal.

17. A power conversion circuit, comprising:
a high-side power switching device comprising a first terminal, a second terminal and a control terminal, wherein the first terminal of the high-side power switching device is configured to receive an input voltage;
a low-side power switching device having a first terminal, a second terminal, and a control terminal, wherein the first terminal of the low-side power switching device is coupled to the second terminal of the high-side power switching device, and the second terminal of the low-side power switching device is coupled to a reference ground;
a high-side driving circuit for driving the high-side power switching device, coupled to the control terminal of the high-side power switching device, for controlling the turn-on and turn-off switching of the high-side power switching device, wherein the high-side driving circuit comprises:
an input terminal, configured to receive a high-side switching control signal; an output terminal, coupled to a control terminal of the high-side power switching device and configured to provide a high-side driving signal to control turn-on and turn-off switching of the high-side power switching device; and a power supply terminal, configured to receive a bootstrap voltage; wherein the high-side driving circuit is configured to: in a startup phase or an initialization phase of the high-side driving circuit, output the high-side driving signal after a delay period has elapsed since the bootstrap voltage reaches or exceeds a first under-voltage threshold; and in a stable operation state of the high-side driving circuit, stop outputting the high-side driving signal in response to the bootstrap voltage becoming lower than a second under-voltage threshold, wherein the first under-voltage threshold is lower than the second under-voltage threshold;
a low-side driving circuit, coupled to the low-side power switching device, for controlling the turn-on and turn-off switching of the low-side power switching device; and
a bootstrap capacitor coupled between the power supply terminal of the high-side driving circuit and a common terminal of the high-side power switching device and the low-side power switching device and configured to provide the bootstrap voltage for the high-side driving circuit.

18. A method for operating a high-side driving circuit, wherein the high-side driving circuit is provided with a supply voltage by a bootstrap capacitor and is configured to output a high-side driving signal to drive a high-side power switching device, wherein the method comprises:
detecting whether the supply voltage becomes higher than a first under-voltage threshold in a start-up phase or an initialization phase of the high-side driving circuit;
outputting the high-side driving signal after a delay period has elapsed since the supply voltage reaches or exceeds the first under-voltage threshold;
detecting whether the supply voltage becomes lower than a second under-voltage threshold during a stable operation state of the high-side driving circuit; and
stopping outputting the high-side driving signal when the supply voltage becomes lower than the second under-voltage threshold, wherein the first under-voltage threshold is lower than the second under-voltage threshold.

19. The method of claim 18, further comprising:
when the supply voltage becomes lower than a shutdown threshold, the under-voltage lockout circuit switches to a first operation mode;
when a number of logic high-level pulses of the high-side driving signal output by the high-side driving circuit reaches a predetermined number, the under-voltage lockout circuit switches to the second operation mode,
wherein the shutdown threshold is lower than or equal to the first under-voltage threshold.
